(19) United States
(12) Patent Application Publication
(10) Pub. No.: US 2007/0059940 A1
(43) Pub. Date: Mar. 15, 2007

(54) Photosensitizer, semiconductor electrode, and photoelectric conversion device

(75) Inventors: Ashraful Islam, Ikoma-shi (JP); Naoki Koide, Kashihara-shi (JP); Kayo Kakutani, Kashihara-shi (JP); Liyuan Han, Kitakatsuragi-gun (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, Osaka (JP)

(21) Appl. No.: 11/483,189

(22) Filed: Jul. 10, 2006

(30) Foreign Application Priority Data
Jul. 8, 2005 (JP) 2005-200080 (P)
Jun. 28, 2006 (JP) 2006-178219 (P)

(51) Int. Cl. H01L 21/302

(52) U.S. Cl. 438/719

(57) ABSTRACT

A photosensitizer containing guanidine derivative expressed in General Formula (a) as 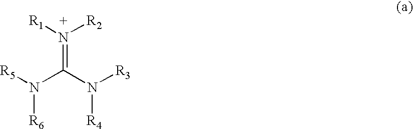
and a photosensitizer expressed in General Formula (X) as D^{(m+m′)-}(A⁺)ₘ(A^{′+})_{m′} or in General Formula (Y) as D^{(m+m′+n)-}(A⁺)ₘ(A^{′+})_{m′}(B⁺)ₙ (where D has a molecular structure capable of absorbing visible light or infrared ray, A and A′ represent the guanidine derivative, and B represents an ion other than the guanidine derivative), and a semiconductor electrode and a photoelectric conversion device employing the photosensitizer are provided. A photosensitizer having a novel structure as well as a semiconductor electrode and a photoelectric conversion device employing the photosensitizer are thus provided.

This nonprovisional application is based on Japanese Patent Applications Nos. 2005-200080 and 2006-178219 filed with the Japan Patent Office on Jul. 8, 2005 and Jun. 28, 2006, respectively, the entire contents of which are hereby incorporated by reference.

### FIELD OF THE INVENTION

The present invention relates to a photosensitizer, and a semiconductor electrode and a photoelectric conversion device using the same.

### DESCRIPTION OF THE BACKGROUND ART

Japanese Patent Laying-Open No. 01-220380 has disclosed, as a solar cell of a new type, a photoelectrochemical dye-sensitized solar cell achieved by applying photo-induced electron transfer of metal complex in recent years. The dye-sensitized solar cell is constituted of a semiconductor electrode, a counter electrode, and an electrolyte layer sandwiched between these electrodes. A bipyridine metal complex is adsorbed on a surface of the semiconductor electrode serving as a photoelectric conversion material, as a photosensitizer having absorption spectrum in a visible light range.

In addition, in order to improve conversion efficiency in the dye-sensitized solar cell, various new photosensitizers have been developed. For example, International Publication No. WO94/04479 Pamphlet and U.S. Pat. No. 6,245,988 disclose various pyridine metal complexes. Moreover, Japanese Patent Laying-Open No. 2003-212851 discloses a dye-sensitized solar cell employing terpyridine diketonate Ru complex attaining wider spectral sensitivity. Currently, however, the cell employing these photosensitizers is not satisfactory in terms of the photoelectric conversion efficiency.

Further, Japanese Patent Laying-Open No. 2001-226607 describes a ruthenium complex dye as well as various kinds of counterions in the text. This publication, however, does not specifically describe how the counterions are structured and how characteristics are improved by using such ions.

An object of the present invention is to provide a photosensitizer having a new structure as well as a semiconductor electrode and a photoelectric conversion device using the photosensitizer.

### SUMMARY OF THE INVENTION

A photosensitizer according to the present invention is characterized by containing guanidine derivative expressed in General Formula (a) as

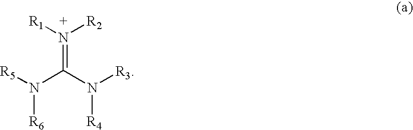

Here, in Formula (a), each of R₁, R₂, R₃, R₄, R₅, R₆ is a substituent independently selected from the group consisting of hydrogen atom, substituted alkyl group, unsubstituted alkyl group, aryl group, substituted heteroaryl group, unsubstituted heteroaryl group, amino group, alkylamino group, dialkylamino group, and —CXNH₂ (where X is O, S or NH), and at least two of R₁, R₂, R₃, R₄, R₅, R₆ may be linked to each other to form a ring structure.

According to the present invention, a photosensitizer capable of extracting a current more efficiently than in the conventional example can be obtained.

In addition, a dye-sensitized semiconductor electrode and a dye-sensitized solar cell employing the photosensitizer according to the present invention can achieve high photoelectric conversion efficiency.

Preferably, in the photosensitizer of the present invention, at least one of R₁, R₂, R₃, R₄, R₅, R₆ in General Formula (a) is hydrogen atom. Here, more preferably, all of R₁, R₂, R₃, R₄, R₅, R₆ in General Formula (a) are hydrogen atoms.

In addition, preferably, at least one of R₁, R₂, R₃, R₄, R₅, R₆ in General Formula (a) is hydrogen atom, and more preferably, at least one of them is alkyl group having carbon number 1 to 18. Here, the guanidine derivative is preferably expressed in a chemical formula below as

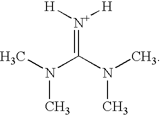

Moreover, the present invention also provides a photosensitizer expressed in General Formula (X) as
D^{(m+m′)}(A⁺)ₘ(A^{′+})_{m′} General Formula (X)
where D has a molecular structure capable of absorbing visible light or infrared ray, A and A′ represent the guanidine derivative according to the present invention described above, m is any natural number selected from among 1 to 4, m′ is any integer selected from among 0 to 3, and m+m′ is any natural number selected from among 1 to 4, or a photosensitizer expressed in General Formula (Y) as
D^{(m+m′+n)}(A⁺)ₘ(A^{′+})_{m′}(B⁺)ₙ General Formula (Y)
where D has a molecular structure capable of absorbing visible light or infrared ray, A and A′ represent the guanidine derivative according to the present invention described above, B represents an ion other than the guanidine derivative, m is any natural number selected from among 1 to 3, m′ is any integer selected from among 0 to 2, n is any natural number selected from among 1 to 3, and m+m′+n is any natural number selected from among 1 to 4.

Preferably, in the photosensitizer of the present invention expressed in General Formula (X) or General Formula (Y) above, D is Ru metal complex.

Preferably, in the photosensitizer of the present invention expressed in General Formula (X) or General Formula (Y) above, D is metal complex having any structure selected from the group consisting of bipyridine, terpyridine and quarterpyridine.

The present invention provides a semiconductor electrode employing any photosensitizer of the present invention described above.

The present invention also provides a photoelectric conversion device including the semiconductor electrode of the present invention described above, a carrier transport layer, and a counter electrode.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross-sectional view showing a basic structure of a dye-sensitized solar cell according to the present invention.

### DESCRIPTION OF THE PREFERRED EMBODIMENTS

(Photosensitizer)

As a result of dedicated study of a photosensitizer modifying the semiconductor electrode, the present inventors have found that a dye-sensitized semiconductor electrode and a dye-sensitized solar cell attaining excellent photoelectric conversion efficiency and high performance, i.e., capable of efficiently extracting a current, can be obtained by having at least one guanidine derivative in a molecular structure of the photosensitizer, and completed the present invention.

Specifically, the photosensitizer of the present invention contains the guanidine derivative expressed in General Formula (a) as

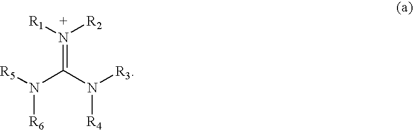

Here, in Formula (a), each of R₁, R₂, R₃, R₄, R₅, R₆ is a substituent independently selected from the group consisting of hydrogen atom, substituted alkyl group, unsubstituted alkyl group, aryl group, substituted heteroaryl group, unsubstituted heteroaryl group, amino group, alkylamino group, dialkylamino group, and —CXNH₂ (where X is O, S or NH). In General Formula (a), two or more of R₁, R₂, R₃, R₄, R₅, R₆ may be linked to each other to form a ring structure.

Preferably, in the guanidine derivative of the present invention, in General Formula (a), at least one of R₁, R₂, R₃, R₄, R₅, R₆ is hydrogen atom. Here, more preferably, all of R₁, R₂, R₃, R₄, R₅, R₆ are hydrogen atoms. In addition, in the guanidine derivative of the present invention, preferably, at least one of R₁, R₂, R₃, R₄, R₅, R₆ is alkyl group having carbon number 1 to 18, and more preferably, at least one of R₁, R₂, R₃, R₄, R₅, R₆ is hydrogen atom and at least one of them is alkyl group having carbon number 1 to 18.

Specific examples of R₁, R₂, R₃, R₄, R₅, R₆ other than the hydrogen atom in Chemical Formula (a) include the following.

Straight-chain or branched-chain alkyl group having carbon number 1 to 18 is preferred as the alkyl group. If the carbon number exceeds 18, the molecule of the photosensitizer may become too great in size to be able to adsorb to the surface of the semiconductor electrode at sufficient density. Specific examples of the alkyl group include methyl, ethyl, propyl, isopropyl, butyl, isobutyl, pentyl, neopentyl, hexyl, heptyl, oxyl, nonyl, decyl, and the like. In addition, from the viewpoint of adsorption density of the sensitizer, the carbon number of the alkyl group is preferably within a range from 1 to 8.

Examples of the substituted alkyl group include alkyl groups in which hydrogen of the alkyl group is substituted with halogen atom such as fluorine, chlorine and bromine, or nitrate group, sulfonic acid group, or carboxylic acid group.

Examples of aryl group include phenyl, methylphenyl, t-butylphenyl, carboxyphenyl, and the like.

Heteroaryl may be five-membered or six-membered ring containing at least one N, S, and/or O as heteroatom, and examples thereof include pyrrole, furan, pyridine, pyrimidine, thiazoline, quinoline, imidazole, benzimidazole, benzoxazole, benzothiazole, indolenine, and the like. Alternatively, heteroaryl may be such that hydrogen is substituted with halogen atom, amine group or the like.

Preferably, alkylamino group and dialkylamino group have the carbon number within a range from 1 to 18. If the carbon number exceeds 18, the molecule of the dye may become too great in size to be able to adsorb to the surface of the semiconductor electrode at sufficient density. Specific examples of the alkylamino group and dialkylamino group include methylamino, ethylamino, propylamino, butylamino, pentylamino, dimethylamino, diethylamino, dipropylamino, dibutylamino, dipentylamino, and the like. In addition, from the viewpoint of adsorption density of the sensitizer, the carbon number of the alkylamino group and the dialkylamino group is preferably within a range from 1 to 5.

Alternatively, each of R₁, R₂, R₃, R₄, R₅, R₆ may independently be carbamoyl group (—CONH₂), thiocarbamoyl group (—CSNH₂), or amidino group (—CNHNH₂).

Specific examples of the guanidine derivative of the present invention include those as expressed in Chemical Formulas 1 to 19 in the following, and among others, those expressed in Chemical Formula 1 and Chemical Formula 12 are preferred.

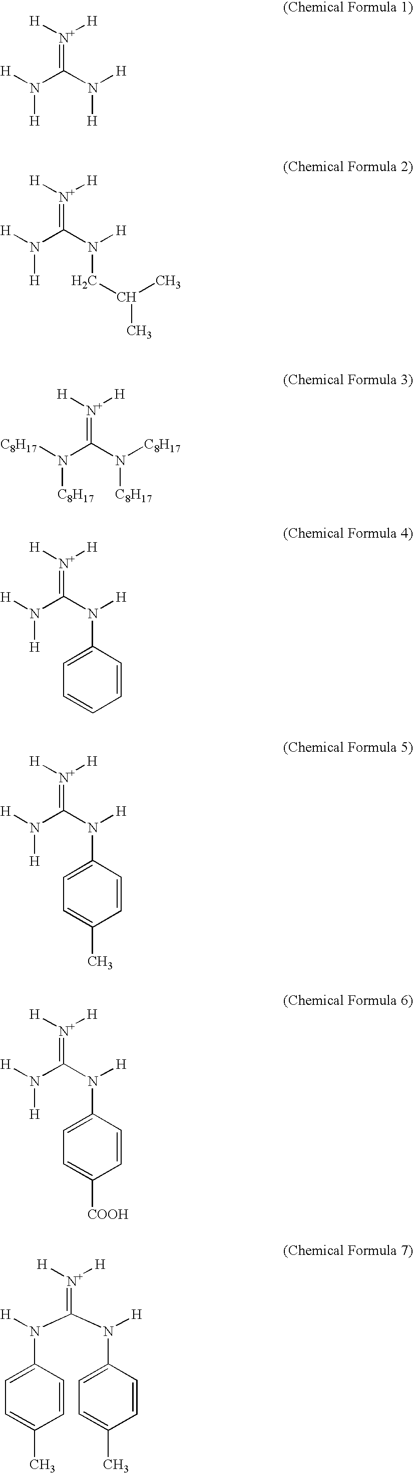

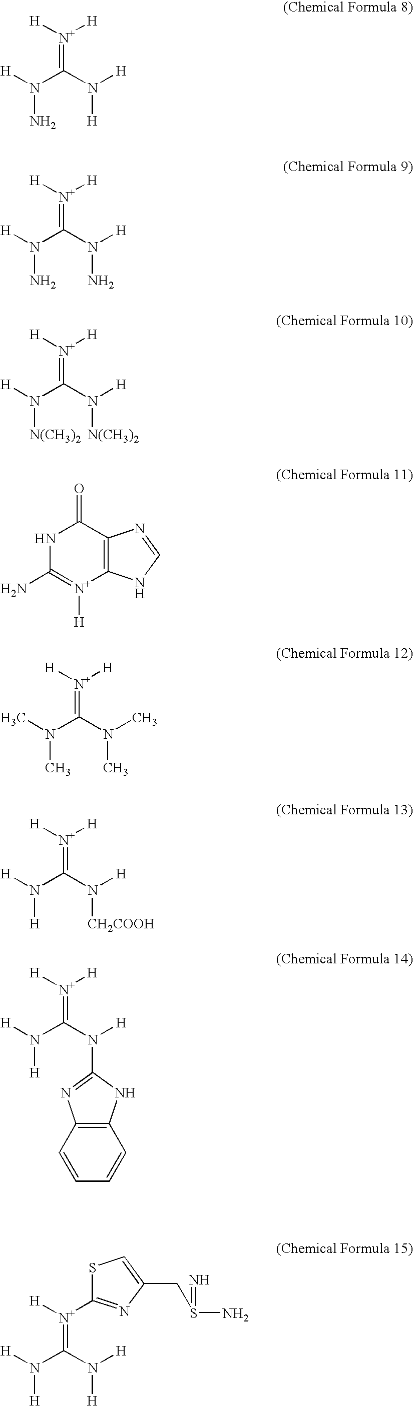

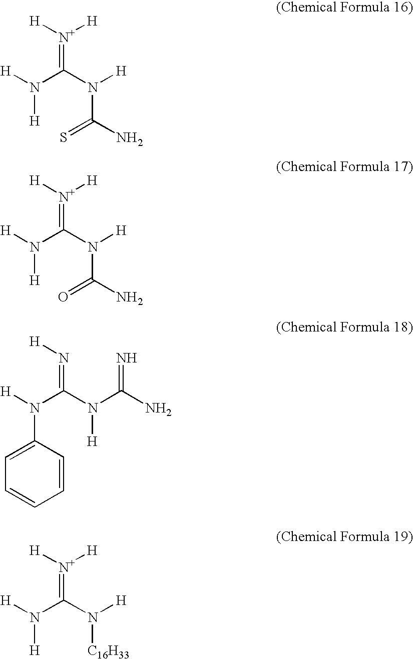

In addition, the present invention provides as a more preferable photosensitizer, a photosensitizer expressed in General Formula (X) or General Formula (Y) below.
D^{(m+m′)}(A⁺)ₘ(A^{′+})_{m′} General Formula (X)

Here, in General Formula (X), A and A′ represent the guanidine derivative described above. In addition, in General Formula (X), D has a molecular structure capable of absorbing visible light or infrared ray, m is any natural number selected from among 1 to 4, m′ is any integer selected from among 0 to 3, and m+m′ is any natural number selected from among 1 to 4,
D^{(m+m′+n)-}(A⁺)ₘ(A^{′+})_{m′}(B⁺)ₙ General Formula (Y)

Here, in General Formula (Y), A and A′ represent the guanidine derivative described above. In addition, in General Formula (Y), D has a molecular structure capable of absorbing visible light or infrared ray, B represents an ion other than the guanidine derivative, m is any natural number selected from among 1 to 3, m′ is any integer selected from among 0 to 2, n is any natural number selected from among 1 to 3, and m+m′+n is any natural number selected from among 1 to 4.

In general, molecular structure D in General Formula (X) or (Y) should only be a structure capable of absorbing light from 400 nm to 1000 nm. For example, an azo-type structure, a quinone-type structure, a quinonimine-type structure, a quinacridone-type structure, a squarylium-type structure, a cyanine-type structure, a merocyanine-type structure, a triphenylmethane-type structure, a xantene-type structure, a porphyrin-type structure, a phthalocyanine-type structure, a peryline-type structure, an indigo-type structure, a naphthalocyanine-type structure, an oxazin-type structure, an anthraquinone-type structure, a coumarin-type structure, or a metal complex structure is preferably employed.

In order to inject photo-excited electrons in the photosensitizer into the semiconductor electrode, molecular structure D preferably has an anchor group that can adsorb to the semiconductor electrode. As the anchor group, —COOH group, —PO(OH)₂ group, —SO₃H group, and the like may be used.

Among the structures described above as molecular structure D, the metal complex is preferred, and examples of metals used in the metal complex include Ni, Fe, Co, Ru, Pt, Mn, Ir, Pd, Os, Rh, and the like. Here, from the viewpoint of the photoelectric conversion efficiency, Ru complex is preferably used. Most preferably, the metal complex having any structure selected from the group consisting of bipyridine, terpyridine and quarterpyridine structure is employed for its high quantum yield and good durability to light.

B in General Formula (Y) is not particularly limited, so long as an ion (cation) other than the guanidine derivative is employed. Examples of the ion include a cation including quaternary nitrogen, an alkali metal ion, an alkaline earth metal ion, a tetraalkylphosphonium ion, and the like. Among these ions, the cation including quaternary nitrogen is preferred. Specific examples of cations including quaternary nitrogen include an ammonium ion, a diethylammonium ion, a tetrapropylammonium ion, a tetrabutylammonium ion, a pyridinium ion, an alkylpyridinium ion, and the like. Among these ions, the ammonium ion, the diethylammonium ion, the tetrapropylammonium ion, and the tetrabutylammonium ion are more preferable, and the tetrabutylammonium ion is particularly preferable. Here, if n is set to 2 or greater, B may be represented by combination of the same ions, or combination of different ions.

Specific examples of the photosensitizer containing Ru complex and guanidine derivative in the present invention include those expressed in the following Chemical Formulas b, c, d, e, f, g, h, and i.

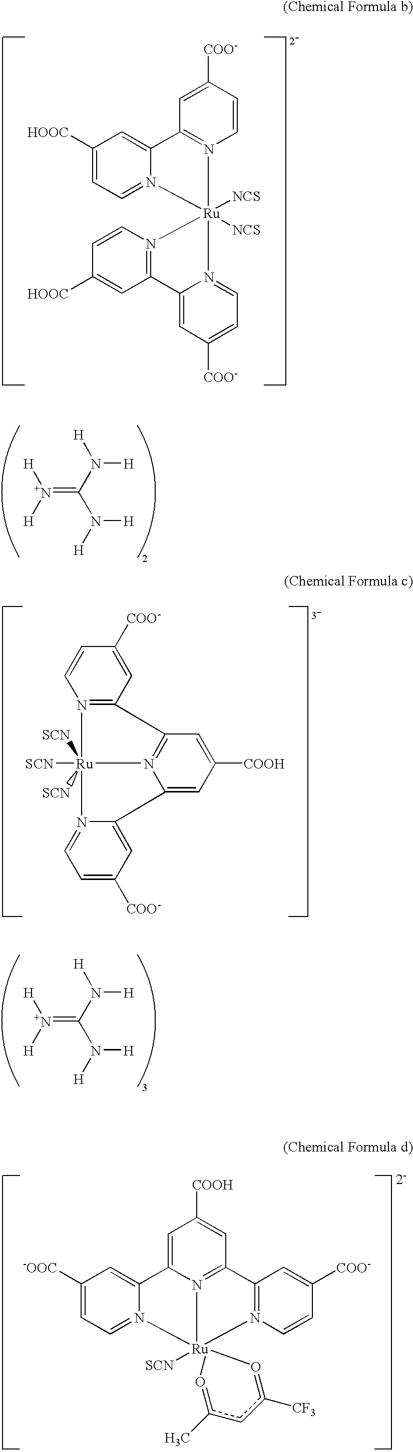

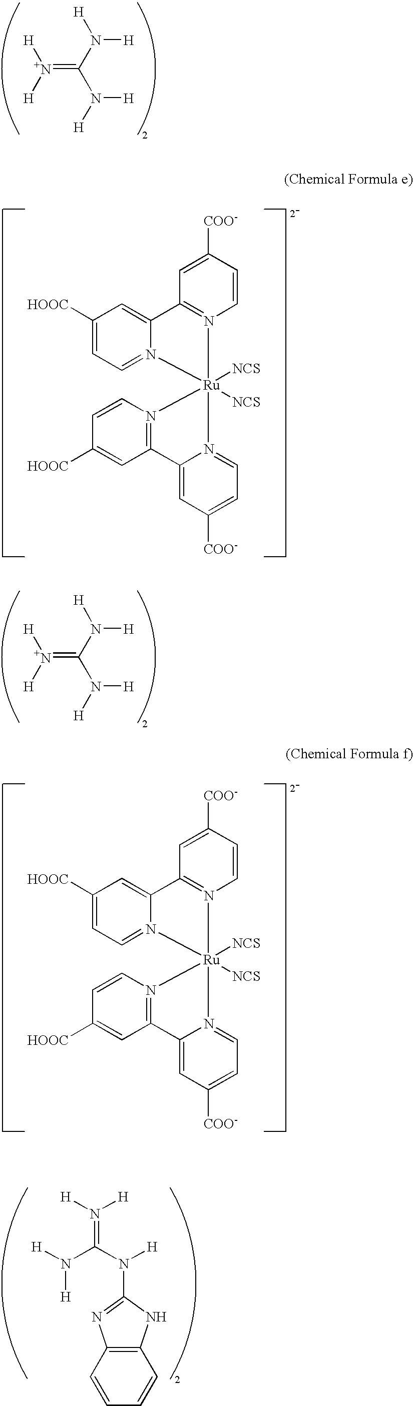

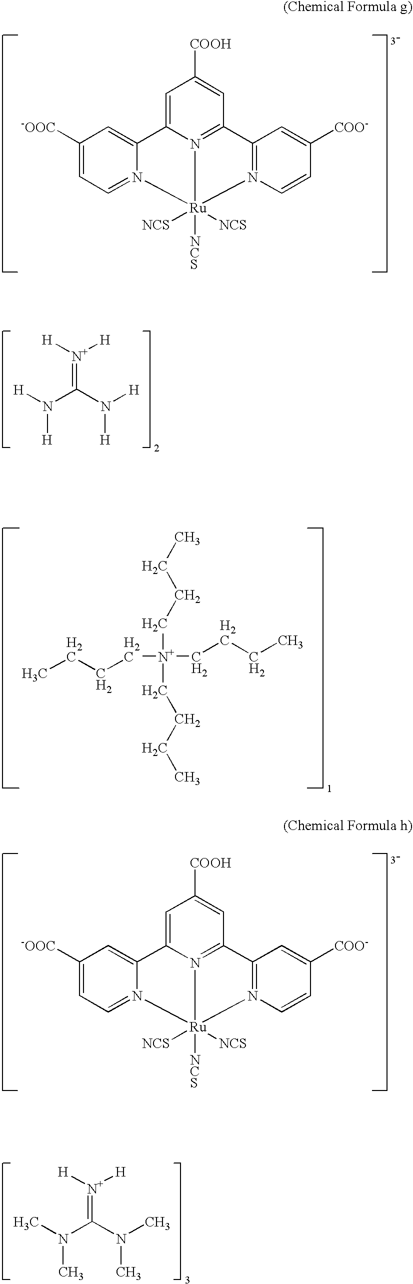

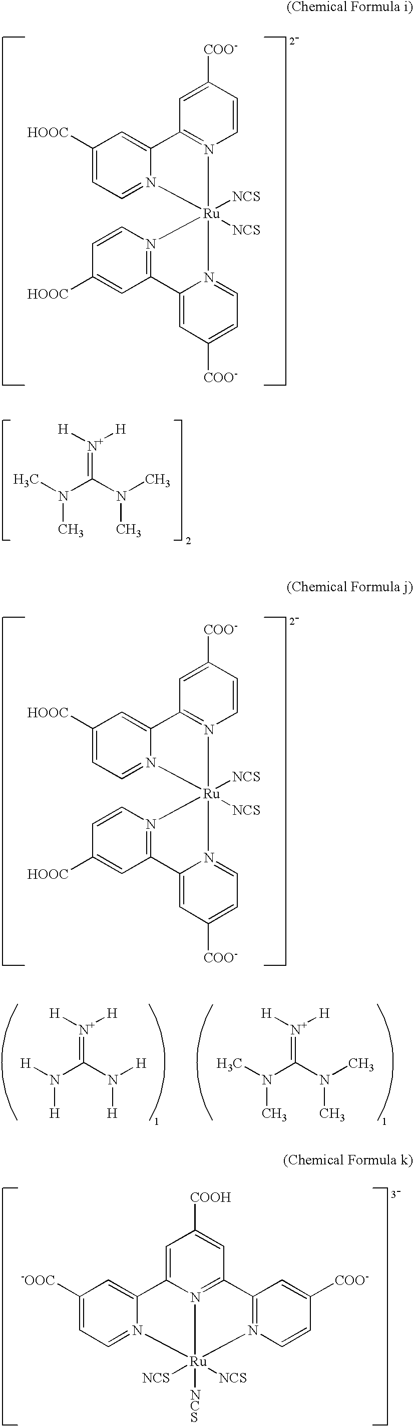

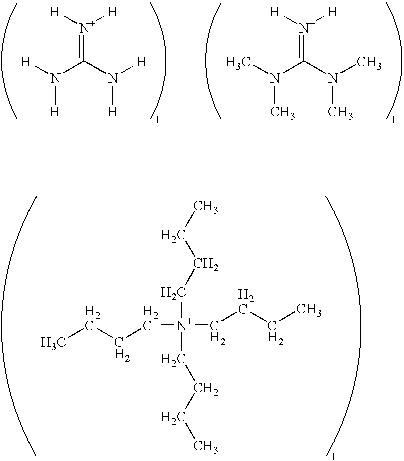

(Method of Manufacturing Photosensitizer)

The photosensitizer according to the present invention shown in General Formula (X) or General Formula (Y) above can be manufactured by synthesizing, for example, pyridine-type ruthenium complex as molecular structure D capable of absorbing visible light or infrared ray and by causing the pyridine-type ruthenium complex to react with a compound serving as a material for the guanidine derivative in General Formula (a).

For pyridine-type ruthenium complex, known substances such as cis-dithiocyanato-bis(4,4′-dicarboxyl-2,2′-bipyridine) ruthenium (II) complex (commonly called N3 dye), cis-dithiocyanato-bis(4,4′-dicarboxyl-2,2′-bipyridine) ruthenium (II) bis-tetrabutylammonium complex (commonly called N719 dye), trithiocyanato(4,4′,4″-tricarboxy-2,2′:6′,2″-terpyridine) ruthenium (II) tri-tetrabutylammonium complex (commonly called black dye), and the like may be used. Here, the bipyridine-type ruthenium complex can be synthesized with reference to the method described, for example, in known document, J. Am. Chem. Soc. 115 (1993) 6382. In addition, the terpyridine-type ruthenium complex can be synthesized with reference to known document, J. Am. Chem. Soc. 123 (2001) 1613. The quarterpyridine-type ruthenium complex can be synthesized with reference to the method described in Japanese Patent Laying-Open No. 2002-193935.

For the compound shown in Chemical Formula 1, commercially available guanidine hydrochloride (chemical formula: CH₆N₃Cl) may be used as a compound serving as the material for the guanidine derivative in General Formula (a). For the compounds shown in Chemical Formulas 2 to 11, 1-isobutyl guanidine hydrochloride (Chemical Formula 2), 1,1,3,3-tetra-n-octylguanidine hydrochloride (Chemical Formula 3), 1-phenylguanidine hydrochloride (Chemical Formula 4), 1-(p-tolyl) guanidine hydrochloride (Chemical Formula 5), 4-guanidinobenzoic acid hydrochloride (Chemical Formula 6), 1,3-(p-tolyl) guanidine hydrochloride (Chemical Formula 7), aminoguanidine hydrochloride (Chemical Formula 8), 1,3-diaminoguanidine hydrochloride (Chemical Formula 9), 1,3-dimethylaminoguanidine hydrochloride (Chemical Formula 10), and guanine hydrochloride (Chemical Formula 11) can be used as materials, respectively. In addition, in order to obtain the compound shown in Chemical Formula 12, commercially available 1,1,3,3-tetramethylguanidine can be used. In order to obtain the compounds shown in Chemical Formulas 13 to 19, guanidoacetic acid (Chemical Formula 13), 2-guanidinobenzimidazole (Chemical Formula 14), S-[2-(guanidino-4-thiazoyl)methyl]isothiourea hydrochloride (Chemical Formula 15), guanylthiourea (Chemical Formula 16), guanylurea sulfate (Chemical Formula 17), phenylbiguanide (Chemical Formula 18), and 1-hexadecylguanidine hydrochloride (Chemical Formula 19) can be used as materials, respectively.

Here, a method of synthesizing the photosensitizer according to the present invention, that is shown in General Formula (X) or General Formula (Y) and to be accomplished, from molecular structure D synthesized previously and the compound used as the material for the guanidine derivative in General Formula (a) may be carried out as follows. Initially, the material for the guanidine derivative is added to a sodium hydroxide solution, and the solution is heated to a temperature of 50 to 100° C. in a dark place. Thereafter, for example, pyridine-type ruthenium complex is dissolved in the solution as molecular structure D, and left for reaction for 30 minutes to 24 hours at a temperature of 50 to 100° C. After the solution is cooled, a solvent is removed. As the solvent, methanol, DMF or the like may be used instead of water. In the manufacturing method above, a calcium hydroxide solution, a magnesium hydroxide solution or the like may be used instead of the sodium hydroxide solution.

(Photoelectric Conversion Device)

The dye-sensitized solar cell representing the photoelectric conversion device employing the photosensitizer of the present invention will now be described. The dye-sensitized solar cell according to the present invention is constituted of the semiconductor electrode to which the photosensitizer of the present invention is adsorbed, the carrier transport layer, and the counter electrode.

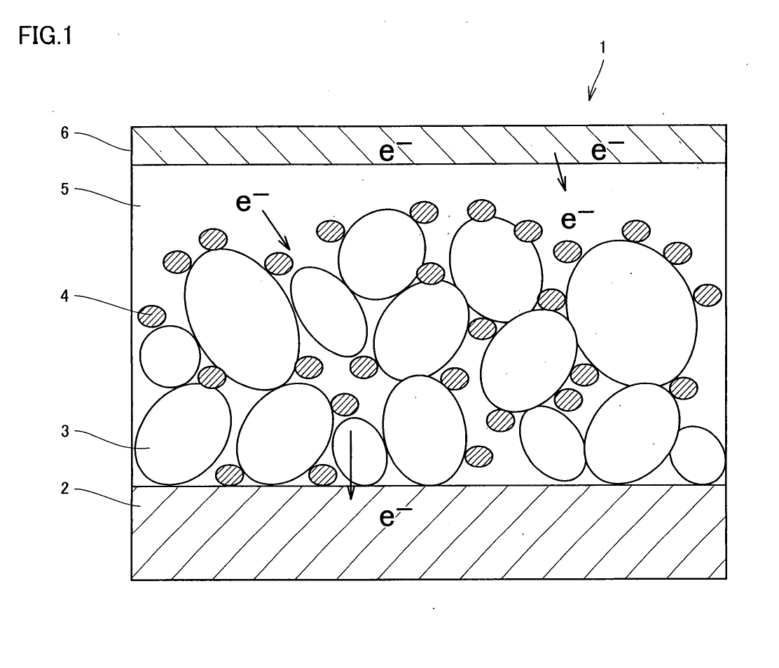

Specifically, description will be given with reference to FIG. 1. FIG. 1 is a schematic cross-sectional view showing a basic structure of the dye-sensitized solar cell according to the present invention. In FIG. 1, a dye-sensitized solar cell 1 according to the present invention is structured such that a semiconductor layer 3 to which a photosensitizer 4 is adsorbed is stacked on a conductive support structure 2 to form the semiconductor electrode, a counter electrode 6 is provided opposed to semiconductor layer 3, and a carrier transport layer 5 is sandwiched between semiconductor electrode 3 and counter electrode 6. In FIG. 1, e⁻ represents electron, and an arrow shows flow of the electron. Any one of conductive support structure 2 and counter electrode 6 is made of a transparent material. Detailed description will be given below.

(Conductive Support Structure)

As the conductive support structure, a support structure having conductivity itself such as those made of metal, or a support structure having a conductive layer on one main surface such as those made of glass, plastic or the like may be used. In the latter case, examples of materials preferable for forming the conductive layer include metals such as gold, platinum, silver, copper, aluminum, indium, and the like, or a material obtained by doping an indium-tin composite oxide and a tin oxide with fluorine. The conductive layer can be formed on the support structure with a known method, using these conductive materials. The conductive layer preferably has a film thickness of 0.02 to 5 μm, from the viewpoint of conductivity.

As to the conductive support structure, as its surface resistance is lower, it is more preferable. Here, the surface resistance is preferably equal to or lower than 40 Ω/sq. If the conductive support structure serves as a light-receiving surface, preferably it is transparent. A thickness of the conductive support structure is not particularly limited, so long as the conductive support structure can provide appropriate strength to the photoelectric conversion device. Taking into account these points and mechanical strength, for example, a conductive support structure provided with a conductive layer made of tin oxide doped with fluorine on glass is given as the representative.

Considering cost, flexibility and the like, the structure provided with the conductive layer on a transparent polymer sheet may be employed. Examples of the transparent polymer sheet include tetraacetylcellulose (TAC), polyethylene terephthalate (PET), polyphenylene sulfide (PPS), polycarbonate (PC), polyalylate (PA), polyetherimide (PEI), phenoxy resin, and the like.

(Semiconductor Electrode)

The semiconductor electrode according to the present invention is normally obtained by forming a semiconductor layer on the conductive support structure and adsorbing thereto the photosensitizer according to the present invention described above.

A method of forming the semiconductor layer is not particularly limited, and a known method may be used. Specifically, for example, any method shown below may be used.

(1) A method of forming the semiconductor layer by applying a suspension containing fine particles of a semiconductor onto the conductive support structure and thereafter drying and calcining the same;

(2) A method of forming the semiconductor layer on the conductive support structure with CVD, MOCVD or the like, using a desired material gas;

(3) A method of forming the semiconductor layer on the conductive support structure with PVD, evaporating, sputtering, or the like, using a material solid; and

(4) A method of forming the semiconductor layer on the conductive support structure with a sol-gel method, an electrochemical method, or the like.

Examples of materials used for the semiconductor layer include titanium oxide (TiO₂), zinc oxide (ZnO), tin oxide (SnO₂), iron oxide (Fe₂O₃), niobium oxide (Nb₂O₅), tungsten oxide, barium titanate, strontium titanate, cadmium sulfide (CdS), lead sulfide (PbS), zinc sulfide (ZnS), indium phosphide (InP), sulfide of copper-indium (CuInS₂), and the like.

Among these materials, titanium oxide, zinc oxide, tin oxide, and niobium oxide are preferable, and titanium oxide is more preferable. One type or at least two types of the materials above may be selected as the material for the semiconductor in the present invention.

The semiconductor layer is preferably formed from a crystal semiconductor of fine particles (nano to microscale). Alternatively, particles of two or more types different in average particle size may be mixed for use. Here, desirably, the average particle size of one type is 10 times as great as that of another. This is because, if larger particles (for example, a particle size of 100 to 500 nm) used for the purpose of improving incident light capture rate and smaller particles (for example, a particle size of 5 to 50 nm) used for the purpose of increasing an amount of dye adsorption are mixed to obtain the semiconductor electrode, the dye-sensitized solar cell including such a semiconductor electrode can achieve improved photoelectric conversion efficiency. Here, the material for particles may be the same among the particles, or different from one another. Particularly, in using particles different in semiconductor material, it is more effective if the semiconductor material attaining stronger adsorption property is smaller in particle size.

Titanium oxide, which is the most preferable material for the semiconductor fine particles, may be fabricated in accordance with the method described in various documents, represented, for example, by “New Synthetic Method: Synthesis and Size/Shape Control of Monodispersed Particle Using Sol-Gel Process”, Materia Japan (in Japanese), 1996, vol. 35, No. 9, pp. 1012-1018, by T. Sugimoto. Titanium oxide used in the present invention encompasses various titanium oxides in a narrow sense, such as anatase-form titanium oxide, rutile-form titanium oxide, amorphous titanium oxide, metatitanic acid, orthotitanic acid, and the like, as well as titanium hydroxide, water-containing titanium oxide and the like.

Two types of crystals. i.e., the anatase-form and the rutile-form, may take either form, depending on a manufacturing method and thermal history, however, mixture of anatase and rutile is common. Here, the anatase-form is preferably included at a high ratio, and the ratio is preferably 80% or higher.

In the present invention, a method of adsorbing the photosensitizer to the semiconductor layer is not particularly limited, and a known method is used. For example, the following method is used. Specifically, the photosensitizer of the present invention is dissolved in an organic solvent such as alcohol, acetonitrile and the like, to prepare a photosensitizer solution. Then, the semiconductor layer formed on the conductive support structure is immersed in the obtained photosensitizer solution. Here, in order to activate the surface of the semiconductor layer, treatment such as heating may be performed as necessary prior to adsorption of the photosensitizer.

A concentration of the photosensitizer in the photosensitizer solution may be adjusted as appropriate, depending on a photosensitizer to be used, a type of the solvent, and a condition for photosensitizer adsorption process. For example, the concentration may be set to 1×10⁻⁵ mol/liter or higher, and preferably to 5×10⁻⁵ to 1×10⁻² mol/liter. A time period for immersion may be set to 5 minutes to 96 hours. Immersion may be performed once or a plurality of times.

If an amount of adsorption of the photosensitizer is small, a photosensitizing effect is insufficient, which is not preferred. In contrast, if an amount of adsorption of the photosensitizer is too large, the photosensitizer that has not adsorbed to the semiconductor electrode floats and the photosensitizing effect is resultantly lowered, which causes lowering in the photoelectric conversion efficiency and is not preferred.

As described above, after the photosensitizer is adsorbed, preferably, the photosensitizer that has not adsorbed should be removed quickly by washing. Preferably, a solvent such as acetone, relatively likely to dry and of which solubility of the photosensitizer is relatively low, is preferred as a washing solvent. In addition, washing is preferably performed in a heated state.

(Carrier Transport Layer)

The carrier transport layer is formed from a conductive material capable of transporting electrons, holes or ions. Examples of the conductive materials (carrier transport material) for forming the carrier transport layer include: a hole transport material such as polyvinyl carbazole and triphenylamine; an electron transport material such as tetranitrofluorenone; a conductive polymer such as polythiophen and polypyrrole; an ion conductor such as liquid electrolyte and polyelectrolyte; an inorganic P-type semiconductor such as copper iodide and copper thiocyanate; and the like.

Among these carrier transport materials, the ion conductor is preferred and the liquid electrolyte containing an oxidation-reduction electrolyte is particularly preferred, because of high photoelectric conversion efficiency. An example of such an oxidation-reduction electrolyte includes an electrolyte containing oxidation-reduction species such as I⁻/I₃⁻ type, Br⁻/Br₃⁻ type, Fe²⁺/Fe³⁺ type, quinone/hydroquinone type, and the like. For example, combination of iodine (I₂) and metal iodide such as lithium iodide (LiI), sodium iodide (NaI), potassium iodide (KI), calcium iodide (CaI₂), or magnesium iodide (MgI₂), combination of I₂ and tetraalkylammonium iodide such as tetraethylammonium iodide (TEAI), tetrapropylammonium iodide (TPAI), tetrabutylammonium iodide (TBAI), or tetrahexylammonium iodide (THAI), and combination of I₂ and imidazolium iodide such as dimethylpropylimidazolium iodide (DMPII), methylpropylimidazolium iodide (MPII), ethylmethylimidazolium iodide (EMII), ethylimidazolium iodide (EII), or hexylmethylimidazolium iodide (HMII), are preferred. Two or more iodide salts mentioned above and I₂ may be combined. Among these combinations, combination of LiI and imidazolium iodide and 12 is particularly preferred.

Examples of the solvent of the liquid electrolyte include a carbonate compound such as propylene carbonate, a nitrile compound such as acetonitrile, alcohols such as ethanol, water, and an aprotic polar substance, and among these substances, the carbonate compound or the nitrile compound is particularly preferred. Two or more types of these solvents may be mixed for use.

A nitrogen-containing aromatic compound such as t-butylpyridine (TBP), or salts other than iodide salts may be added to the liquid electrolyte as an additive.

The concentration of the electrolyte in the liquid electrolyte is preferably set to a value in a range from 0.01 to 1.5 mol/liter and particularly preferably to a value in a range from 0.1 to 0.7 mol/liter.

The polyelectrolyte is implemented by a solid substance capable of bonding to at least one substance containing or composing the oxidation-reduction species, and examples of the polyelectrolyte include a high-polymer compound such as polyethylene oxide, polypropylene oxide, polyethylene succinate, poly-β-propiolactone, polyethyleneimine, and polyalkylene sulfide, or a crosslinked compound thereof, or a substance obtained by adding, as a side chain, a polyether segment or an oligoalkylene oxide structure to functional group of high polymer such as polyphosphazene, polysiloxane, polyvinyl alcohol, polyacrylic acid, polyalkylene oxide, or the like, or a copolymer thereof. Among these substances, a substance having the oligoalkylene oxide structure as the side chain or a substance having the polyether segment as the side chain is particularly preferred.

In order to cause the solid above to contain the oxidation-reduction species, for example, a method of polymerizing under coexistence of a monomer serving as a high-polymer compound and the oxidation-reduction species, a method of dissolving a solid such as a high-polymer compound in a solvent as necessary and thereafter adding the above-described oxidation-reduction species thereto, or other methods may be used. The content of the oxidation-reduction species may be selected as appropriate, depending on necessary ion transport performance.

(Counter Electrode)

The counter electrode is formed by providing a platinum layer or a carbon layer on a support substrate or a protective layer. A known method such as sputtering, electrodeposition, pyrolysis, or the like may be used as a method for forming the platinum layer or the carbon layer. The support substrate or the protective layer may be used as a substrate for the dye-sensitized solar cell. A conventionally known transparent or opaque substrate that is appropriate may be used.

### EXAMPLES

The present invention will be described hereinafter in further detail with reference to examples and comparative examples, however, the present invention is not limited thereto.

### Example 1

Initially, 0.71 mmol guanidine hydrochloride (manufactured by Aldrich, chemical formula: CH₆N₃Cl) was dissolved in 10 ml pure water, to prepare a solution 1. Meanwhile, 0.35 mmol cis-dithiocyanato-bis(4,4′-dicarboxyl-2,2′-bipyridine) ruthenium (II) complex (manufactured by Solaronix, product name: Ru535, commonly called N3 dye) which represents bipyridine ruthenium complex forming molecular structure D in the photosensitizer shown in General Formula (X) was added to 10 ml pure water. While stirring this solution, 0.1 mol/l sodium hydroxide (NaOH) solution was gradually dropped until N3 dye was completely dissolved, to prepare a solution 2. Solution 1 and solution 2 prepared as above were mixed, and the resultant solution was left for reaction for 30 minutes at a temperature of 70° C. in a dark place. After cooled to a room temperature, the reaction solution was filtered. The resultant solid was dried under vacuum, to obtain the compound shown in Chemical Formula b above.

A result of analysis of the product was as follows. Compound b: C₂₈H₂₆N₁₂O₈RuS₂; yield: 75%; calculated value: C=40.82, H=3.18, N=20.40; measured value: C=40.52, H=3.25, N=20.72; and MS (ESIMS): m/z=823.0 (M−H)⁻, 411.0 (M−2H)²⁻, 254.0 [M−2H-(guanidinium)]³⁻.

### Example 2

The compound shown in Chemical Formula c above was obtained as in Example 1, except that commercially available trithiocyanato(4,4′,4″-tricarboxy-2,2′:6′,2″-terpyridine) ruthenium (II) tri-tetrabutylammonium complex of 0.23 mmol (manufactured by Solaronix, product name: N620-1H3TBA, commonly called black dye) representing terpyridine ruthenium complex was used as the material for forming molecular structure D in the photosensitizer shown in General Formula (X), instead of N3 dye.

A result of analysis of the product was as follows. Compound c: C₂₄H₂₇N₁₅O₆RuS₃; yield: 70%; calculated value: C=35.20, H=3.32, N=25.66; measured value: C=34.80, H=3.42, N=25.32; and MS (ESIMS): m/z=818.1 (M−H)⁻, 379.0 [M−H-(guanidinium)]²⁻, 232.6 [M-H-2 (guanidinium)]³⁻.

### Example 3

The compound shown in Chemical Formula d above was obtained as in Example 1, except that 0.35 mmol thiocyanato-1,1,1-trifluoropentane-2,4-dionato(4,4′,4″-tricarboxy-2,2′:6′,2″-terpyridine) ruthenium (II) complex (synthesized in accordance with the method described in Japanese Patent Laying-Open No. 2003-212851) representing terpyridine ruthenium complex was used as the material for forming molecular structure D in the photosensitizer shown in General Formula (X), instead of N3 dye.

A result of analysis of the product was as follows. Compound d: C₂₆H₂₈F₃N₁₀O₈RuS; yield: 70%; calculated value: C=39.10, H=3.53, N=17.54; measured value: C=39.72, H=3.42, N=17.23; and MS (ESIMS): m/z=798.1 (M−H)⁻, 369.0 [M−H-(guanidinium)]²⁻, 226.0 [M−H-2 (guanidinium)]³⁻.

### Example 4

The compound shown in Chemical Formula e above was obtained as in Example 1, except that 0.35 mmol dithiocyanato(4,4′,4″,4′″-tetracarboxy-2,2′:6′,2″:6″,2′″-quarterpyridine) ruthenium (II) complex (synthesized in accordance with the method described in Japanese Patent Laying-Open No. 2002-193935) representing quarterpyridine ruthenium complex was used as the material for forming molecular structure D in the photosensitizer shown in General Formula (X), instead of N3 dye.

A result of analysis of the product was as follows. Compound e: C₂₈H₂₄F₃N₁₂O₈RuS₂; yield: 70%; calculated value: C=40.92, H=2.94, N=20.45; measured value: C=41.23, H=2.83, N=20.10; and MS (ESIMS): m/z=821.1 (M−H)⁻, 410.1 (M−2H)²⁻, 253.3 [M−2H-(guanidinium)]³⁻.

### Example 5

A compound 2-guanidinobenzimidazole (manufactured by Aldrich, chemical formula: C₈H₉N₅) of 0.71 mmol was dissolved in 10 ml HCl of 0.1 mol/l, to prepare a solution 3. Meanwhile, 0.35 mmol N3 dye was dissolved in 10 ml NaOH solution of 0.1 mol/l, to prepare a solution 4. Solution 3 was mixed with solution 4, and the mixture was left for reaction for 30 minutes at a temperature of 60° C. in a dark place. After cooled to a room temperature, the reaction solution was filtered. The resultant solid was dried under vacuum, to obtain the compound shown in Chemical Formula f above.

A result of analysis of the product was as follows. Compound f: C₄₂H₃₄N₁₆O₈RuS₂; yield: 71%; calculated value: C=47.77, H=3.25, N=21.22; measured value: C=47.89, H=3.19, N=21.02; and MS (ESIMS): m/z=1055.1 (M−H)⁻, 527.1 (M−2H)²⁻, 292.7 [M−2H-(2-benzimidazole guanidinium)]³⁻.

### Example 6

The compound shown in Chemical Formula g above was obtained as in Example 1, except that commercially available trithiocyanato(4,4′,4″-tricarboxy-2,2′:6′,2″-terpyridine) ruthenium (II) tri-tetrabutylammonium complex of 0.35 mmol (manufactured by Solaronix, product name: N620-1H3TBA, commonly called black dye) representing terpyridine ruthenium complex was used as the material for forming molecular structure D in the photosensitizer shown in General Formula (X), instead of N3 dye.

A result of analysis of the product was as follows. Compound g: C₃₉H₅₇N₁₃O₆RuS₃; yield: 72%; calculated value: C=46.78, H=5.74, N=18.19; measured value: C=46.52, H=5.64, N=18.24; and MS (ESI-MS): m/z=1000.2 (M−H)⁻, 470.1 [M−H-(guanidinium)]²⁻, 379.0 [M−H-(tetrabutylammonium)]²⁻.

### Example 7

A compound 1,1,3,3-tetramethylguanidine (manufactured by Aldrich, chemical formula: C₅H₁₃N₃) of 0.71 mmol was dissolved in 10 ml HCl of 0.1 mol/l, to prepare a solution 5. Meanwhile, 0.23 mmol black dye was dissolved in 10 ml NaOH solution of 0.1 mol/l, to prepare a solution 6. Solution 5 was mixed with solution 6, and the mixture was left for reaction for 30 minutes at a temperature of 60° C. in a dark place. After cooled to a room temperature, the reaction solution was filtered. The resultant solid was dried under vacuum, to obtain the compound shown in Chemical Formula h above.

A result of analysis of the product was as follows. Compound h: C₃₆H₅₁N₁₅O₆RuS₃; yield: 73%; calculated value: C=43.80, H=5.21, N=21.28; measured value: C=43.65, H=5.14, N=21.34; and MS (ESI-MS): m/z=986.1 (M−H)⁻, 435.1 [M−H-(1,1,3,3-tetramethylguanidinium)]²⁻, 251.3 [M−H-2 (1,1,3,3-tetramethylguanidinium)]³⁻.

### Example 8

The compound shown in Chemical Formula i above was obtained as in Example 7, except that 0.35 mmol N3 dye was used instead of the black dye.

A result of analysis of the product was as follows. Compound i: C₃₆H₄₂N₁₂O₈RuS₂; yield: 71%; calculated value: C=46.20, H=4.52, N=17.96; measured value: C=46.32, H=4.59, N=17.87; and MS (ESI-MS): m/z=934.9 (M-H)⁻, 467.0 (M−2H)²⁻, 272.7 [M−2H-(1,1,3,3-tetramethylguanidinium)]³⁻.

### Example 9

A solution 7 was prepared by dissolving 0.35 mmol N3 dye in 10 ml NaOH solution of 0.05 mol/l. In addition, solution 1 (5 ml) prepared in Example 1 and solution 5 (5 ml) prepared in Example 7 were prepared. Solution 1, solution 5 and solution 7 were mixed, and the mixture was left for reaction for 30 minutes at a temperature of 60° C. in a dark place. After cooled to a room temperature, the reaction solution was filtered. The resultant solid was dried under vacuum, to obtain the compound shown in Chemical Formula j above.

A result of analysis of the product was as follows. Compound j: C₃₂H₃₄N₁₂O₈RuS₂; yield: 70%; calculated value: C=43.68, H=3.89, N=19.10; measured value: C=43.79, H=3.75, N=19.07; and MS (ESI-MS): m/z=878.9 (M−H)⁻, 409.5 [M−H-(guanidinium)]²⁻, 381.5 [M−H-(1,1,3,3-tetramethylguanidinium)]²⁻.

### Example 10

The compound shown in Chemical Formula k above was obtained as in Example 9, except that 0.35 mmol black dye was used instead of N3 dye.

A result of analysis of the product was as follows. Compound k: C₄₃H₆₅N₁₃O₆RuS₃; yield: 70%; calculated value: C=48.85, H=6.20, N=17.22; measured value: C=48.72, H=6.24, N=17.17; and MS (ESI-MS): m/z=1056.3 (M−H)⁻, 815.0 [M-(tetrabutylammonium)]⁻, 349.5 [M-(tetrabutylammonium)-(1,1,3,3-tetramethylguanidinium)]²⁻.

### Example 11

Thereafter, the photosensitizer according to the present invention manufactured in Example 1 and shown in Chemical Formula b was used to fabricate the semiconductor electrode, and this semiconductor electrode was used to fabricate the dye-sensitized solar cell representing the photoelectric conversion device. Initially, commercially available titanium oxide paste (manufactured by Solaronix, product name: Ti-Nanoxide D/SP, average particle size: 13 nm) was applied to a transparent substrate (manufactured by Nippon Sheet Glass Co., Ltd.) in which an SnO₂ film, which is a transparent conductive film, is vapor-deposited on a glass plate using screen printing. Then, the substrate was subjected to predrying for 10 minutes at a temperature of 100° C. and calcined for 30 minutes at a temperature of 500° C., thus obtaining a titanium oxide film having a thickness of 19 μm.

The photosensitizer manufactured in Example 1 and shown in Chemical Formula b was dissolved in ethanol to attain a concentration of 5×10⁻⁴ mol/l, to prepare a photosensitizer solution. Then, the glass plate on which the above-described titanium oxide film was formed was immersed in the solution for 5 hours for adsorption of the photosensitizer to the titanium oxide film, thereby forming the semiconductor electrode.

A platinum film was vacuum deposited on a surface of the transparent conductive film on the transparent substrate similarly structured as above to a thickness of 300 nm, thereby forming the counter electrode. An electrolytic solution was supplied in between the counter electrode and the semiconductor electrode, and the sides thereof were sealed with resin. As the electrolytic solution, a solution obtained by dissolving LiI (0.1 M, manufactured by Aldrich), I₂ (0.05M, manufactured by Aldrich), t-butylpyridine (0.5M, manufactured by Aldrich), and dimethylpropyl imidazolium iodide (0.6M, manufactured by Shikoku Chemicals Corporation) in acetonitrile (manufactured by Aldrich) was used. Thereafter, a lead wire was attached to each electrode, to obtain the dye-sensitized solar cell. The obtained dye-sensitized solar cell was irradiated with light of intensity of 1000 W/m² (AM1.5 solar simulator), and short-circuit current density of 18.1 mA/cm², open-circuit voltage of 0.76V, FF of 0.74, and photoelectric conversion efficiency of 10.2% were obtained.

### Example 12

The dye-sensitized solar cell was manufactured as in Example 11, except for using as the photosensitizer, the photosensitizer manufactured in Example 2 and shown in Chemical Formula c. The obtained dye-sensitized solar cell was irradiated with light of intensity of 1000 W/m² (AM1.5 solar simulator), and short-circuit current density of 21.1 mA/cm², open-circuit voltage of 0.73V, FF of 0.70, and photoelectric conversion efficiency of 10.8% were obtained.

### Example 13

The dye-sensitized solar cell was manufactured as in Example 11, except for using as the photosensitizer, the photosensitizer manufactured in Example 3 and shown in Chemical Formula d. The obtained dye-sensitized solar cell was irradiated with light of intensity of 1000 W/m² (AM1.5 solar simulator), and short-circuit current density of 21.0 mA/cm², open-circuit voltage of 0.73V, FF of 0.70, and photoelectric conversion efficiency of 10.7% were obtained.

### Example 14

The dye-sensitized solar cell was manufactured as in Example 11, except for using as the photosensitizer, the photosensitizer manufactured in Example 4 and shown in Chemical Formula e. The obtained dye-sensitized solar cell was irradiated with light of intensity of 1000 W/m² (AM1.5 solar simulator), and short-circuit current density of 19.5 mA/cm², open-circuit voltage of 0.76V, FF of 0.73, and photoelectric conversion efficiency of 10.8% were obtained.

### Example 15

The dye-sensitized solar cell was manufactured as in Example 11, except for using as the photosensitizer, the photosensitizer manufactured in Example 5 and shown in Chemical Formula f. The obtained dye-sensitized solar cell was irradiated with light of intensity of 1000 W/m² (AM1.5 solar simulator), and short-circuit current density of 17.6 mA/cm², open-circuit voltage of 0.75V, FF of 0.74, and photoelectric conversion efficiency of 9.8% were obtained.

### Example 16

The dye-sensitized solar cell was manufactured as in Example 11, except for using as the photosensitizer, the photosensitizer manufactured in Example 6 and shown in Chemical Formula g. The obtained dye-sensitized solar cell was irradiated with light of intensity of 1000 W/m² (AM1.5 solar simulator), and short-circuit current density of 21.8 mA/cm², open-circuit voltage of 0.74V, FF of 0.71, and photoelectric conversion efficiency of 11.5% were obtained.

### Example 17

The dye-sensitized solar cell was manufactured as in Example 11, except for using as the photosensitizer, the photosensitizer manufactured in Example 7 and shown in Chemical Formula h. The obtained dye-sensitized solar cell was irradiated with light of intensity of 1000 W/m² (AM1.5 solar simulator), and short-circuit current density of 21.2 mA/cm², open-circuit voltage of 0.72V, FF of 0.70, and photoelectric conversion efficiency of 10.7% were obtained.

### Example 18

The dye-sensitized solar cell was manufactured as in Example 11, except for using as the photosensitizer, the photosensitizer manufactured in Example 8 and shown in Chemical Formula i. The obtained dye-sensitized solar cell was irradiated with light of intensity of 1000 W/m² (AM1.5 solar simulator), and short-circuit current density of 17.9 mA/cm², open-circuit voltage of 0.77V, FF of 0.75, and photoelectric conversion efficiency of 10.3% were obtained.

### Example 19

The dye-sensitized solar cell was manufactured as in Example 11, except for using as the photosensitizer, the photosensitizer manufactured in Example 9 and shown in Chemical Formula j. The obtained dye-sensitized solar cell was irradiated with light of intensity of 1000 W/m² (AM1.5 solar simulator), and short-circuit current density of 18.0 mA/cm², open-circuit voltage of 0.76V, FF of 0.75, and photoelectric conversion efficiency of 10.3% were obtained.

### Example 20

The dye-sensitized solar cell was manufactured as in Example 11, except for using as the photosensitizer, the photosensitizer manufactured in Example 10 and shown in Chemical Formula k. The obtained dye-sensitized solar cell was irradiated with light of intensity of 1000 W/m² (AM1.5 solar simulator), and short-circuit current density of 21.2 MA/cm2, open-circuit voltage of 0.75V, FF of 0.71, and photoelectric conversion efficiency of 11.3% were obtained.

### Comparative Example 1

The dye-sensitized solar cell was manufactured as in Example 11, except for using as the photosensitizer, known cis-dithiocyanato-bis(4,4′-dicarboxyl-2,2′-bipyridine) ruthenium (II) bis-tetrabutylammonium complex (manufactured by Solaronix, product name: Ru535 bis TBA, commonly called N719 dye). The obtained dye-sensitized solar cell was irradiated with light of intensity of 1000 W/m² (AM1.5 solar simulator), and short-circuit current density of 17.3 mA/cm², open-circuit voltage of 0.74V, FF of 0.72, and photoelectric conversion efficiency of 9.2% were obtained.

### Comparative Example 2

The dye-sensitized solar cell was manufactured as in Example 11, except for using as the photosensitizer, known trithiocyanato(4,4′,4″-tricarboxy-2,2′:6′,2″-terpyridine) ruthenium (II) tri-tetrabutylammonium complex (manufactured by Solaronix, product name: N620-1H3TBA, commonly called black dye). The obtained dye-sensitized solar cell was irradiated with light of intensity of 1000 W/m² (AM1.5 solar simulator), and short-circuit current density of 19.8 mA/cm², open-circuit voltage of 0.70V, FF of 0.70, and photoelectric conversion efficiency of 9.7% were obtained.

As a result of comparison of Examples 11 to 20 with Comparative Examples 1 and 2, it was found that use of the photosensitizer containing the guanidine derivative shown in General Formula (a) improves conversion efficiency.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A photosensitizer containing guanidine derivative expressed in General Formula (a) as 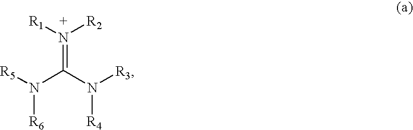
where each of R₁, R₂, R₃, R₄, R₅, R₆ is a substituent independently selected from the group consisting of hydrogen atom, substituted alkyl group, unsubstituted alkyl group, aryl group, substituted heteroaryl group, unsubstituted heteroaryl group, amino group, alkylamino group, dialkylamino group, and —CXNH₂ (where X is O, S or NH), and at least two of R₁, R₂, R₃, R₄, R₅, R₆ may be linked to each other to form a ring structure.

2. The photosensitizer according to claim 1, wherein
at least one of R₁, R₂, R₃, R₄, R₅, R₆ in General Formula (a) is hydrogen atom.

3. The photosensitizer according to claim 2, wherein
all of R₁, R₂, R₃, R₄, R₅, R₆ in General Formula (a) are hydrogen atoms.

4. The photosensitizer according to claim 1, wherein
at least one of R₁, R₂, R₃, R₄, R₅, R₆ in General Formula (a) is alkyl group having carbon number 1 to 18.

5. The photosensitizer according to claim 4, wherein
the guanidine derivative is expressed in a chemical formula below as

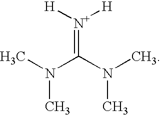

6. A photosensitizer expressed in General Formula (X) as
D^{(m+m′)-}(A⁺)ₘ(A^{′+})_{m′} General Formula (X), wherein
D has a molecular structure capable of absorbing visible light or infrared ray, A and A′ represent the guanidine derivative according to claim 1, m is any natural number selected from among 1 to 4, m′ is any integer selected from among 0 to 3, and m+m′ is any natural number selected from among 1 to 4.

7. The photosensitizer according to claim 6, wherein
D in said General Formula (X) is Ru metal complex.

8. The photosensitizer according to claim 7, wherein
D in said General Formula (X) is metal complex having any structure selected from the group consisting of bipyridine, terpyridine and quarterpyridine.

9. A photosensitizer expressed in General Formula (Y) as
D^{(m+m′+n)-}(A⁺)ₘ(A^{′+})_{m′}(B⁺)ₙ General Formula (Y), wherein
D has a molecular structure capable of absorbing visible light or infrared ray, A and A′ represent the guanidine derivative according to claim 1, B represents an ion other than the guanidine derivative, m is any natural number selected from among 1 to 3, m′ is any integer selected from among 0 to 2, n is any natural number selected from among 1 to 3, and m+m′+n is any natural number selected from among 1 to 4.

10. The photosensitizer according to claim 9, wherein
D in said General Formula (Y) is Ru metal complex.

11. The photosensitizer according to claim 10, wherein
D in said General Formula (Y) is metal complex having any structure selected from the group consisting of bipyridine, terpyridine and quarterpyridine.

12. A semiconductor electrode having the photosensitizer according to claim 1.

13. A photoelectric conversion device, comprising the semiconductor electrode according to claim 12, a carrier transport layer, and a counter electrode.

14. A semiconductor electrode having the photosensitizer according to claim 6.

15. A photoelectric conversion device, comprising the semiconductor electrode according to claim 14, a carrier transport layer, and a counter electrode.

16. A semiconductor electrode having the photosensitizer according to claim 9.

17. A photoelectric conversion device, comprising the semiconductor electrode according to claim 16, a carrier transport layer, and a counter electrode.
